(19) United States
(12) Patent Application Publication
(10) Pub. No.: US 2018/0336815 A1
(43) Pub. Date: Nov. 22, 2018

(54) LED PANEL DISPLAY STRUCTURE

(71) Applicant: KEYCORE TECHNOLOGY CORP., Hsinchu County (TW)

(72) Inventors: Wei-Cheng Lin, Hsinchu County (TW); Chien-Jen Hsiao, Hsinchu County (TW); Shih-Hsiu Tseng, Hsinchu County (TW)

(21) Appl. No.: 15/609,045

(22) Filed: May 31, 2017

(30) Foreign Application Priority Data
May 17, 2017 (TW) 106116314

(51) Int. Cl. G09G 3/32; G06F 3/041; G06F 3/042; G06K 9/00; H01L 27/15; H01L 25/075; H01L 25/16; H01L 33/62; H01L 27/12; H01L 23/498

(52) U.S. Cl. CPC G09G 3/32; G06F 3/0412; G06F 3/0421; G06K 9/0004; H01L 27/156; G09G 2300/0452; H01L 25/167; H01L 33/62; H01L 27/124; H01L 23/4985; H01L 27/1218; H01L 25/0753

(57) ABSTRACT

An LED panel display structure includes a base member, on which a longitudinally extended first electrode layer, a transversely extended second electrode layer, a plurality of switch elements, a plurality of LED elements and a control chip are provided. The switch elements respectively have a first pin, a second pin and a third pin; and the first and the second pins are electrically connected to the first and the second electrode layer, respectively. The LED elements respectively have a first lead and a second lead. The first leads and the second leads are electrically connected to the third pins and a ground, respectively. The control chip is electrically connected to the first and the second electrode layer. With these arrangements, only one control chip is needed to control all the LED elements to largely reduce the manufacturing cost and enable increased resolution of the LED panel display structure.

This application claims the priority benefit of Taiwan patent application number 106116314 filed on May 17, 2017.

### FIELD OF THE INVENTION

The present invention relates to an LED panel display structure, and more particularly, to an LED panel display structure that uses only one control chip to control a plurality of light-emitting diode (LED) elements to achieve the purpose of saving cost and realizing increased resolution per unit length.

### BACKGROUND OF THE INVENTION

Progressive scan is used for all liquid-crystal displays (LCDs), i.e. all the lines or rows of each image on the LCD are scanned in sequence from top to bottom. A gate driver IC (integrated circuit) is connected to the gates of all transistors in each row to control the ON/OFF of these transistors, and all the transistors in the same row are turned on at the same time during signal scanning. Only when the transistors have been turned on, can source driver ICs start transmitting control voltage, which controls the brightness, gray scale and color of each row, to the pixels of the panel column by column via channels formed by the sources and drains of the transistors. The gate driver IC is also referred to as row driver or scan driver because it controls the on/off of the transistors in each row. The source driver IC is also referred to as column driver or data driver because it inputs data voltage column by column to each row when the gate driver ICs operate row by row.

Taking super extended graphics array (SXGA) as an example, it refers to a display resolution of 1280×1024 pixels, meaning total 1280 columns and 1024 rows of pixels are included in a pixel array within an active display area. For each pixel to present a color, the pixel has to include three primary colors of red, green and blue. Therefore, the SXGA must have total 1280×3=3840 column data. In the case of using gate driver ICs having 256 pins each and source driver ICs having 384 pins each, total 4 gate driver ICs (1024/256=4) and 10 source driver ICs (1280×3/384=10) are required to drive an SXGA LCD panel. Alternatively, when the above-mentioned gate and source driver ICs are used to drive an extended graphics array (XGA) LCD panel (having a resolution of 1024×768), 3 gate driver ICs and 8 source driver ICs are needed. These are the currently most frequently used display resolutions as well as gate and source driver IC combinations.

That is, more driver ICs are required for the LCD display having a higher resolution. However, it is difficult to provide so many driver ICs within each very limited unit area, forming a hindrance to the realization of a small-sized display with a high resolution.

### SUMMARY OF THE INVENTION

To overcome the shortcomings of the prior art LCD displays, it is a primary object of the present invention to provide an LED panel display structure that can be manufactured at reduced cost and needs only one control chip to control the whole LED panel display, so that a high resolution can also be achieved on a small-sized panel display.

To achieve the above and other objects, the LED panel display structure provided according to the present invention includes a base member, a first electrode layer, a second electrode layer, a plurality of switch elements, a plurality of LED elements and a control chip.

The base member has a first side and an opposite second side; the first electrode layer includes a plurality of first electrode wirings provided on the first side of the base member to extend longitudinally; and the second electrode layer includes a plurality of second electrode wirings provided on the first side of the base member to extend transversely and cross over the first electrode wirings.

The switch elements are provided on the first side of the base member. Each of the switch elements includes a first pin, a second pin and a third pin; and the first and the second pin are electrically connected to the first and the second electrode wirings, respectively.

The LED elements are provided on the first side of the base member. Each of the LED elements includes a first lead and a second lead. The first leads are electrically connected to the third pins of the switch elements, and the second leads are electrically connected to a ground.

The control chip is electrically connected to the first and the second electrode layer.

Since the LED panel display structure of the present invention uses only one control chip, the whole LED panel display can be manufactured at largely reduced cost. Further, since the present invention needs only one control chip to control all the LED elements of the LED panel display, the omitted control chips result in more space saved in each unit area for arranging more LED elements in even a small-sized panel, which in turn enables image quality of very high resolution as well as integration of touch and fingerprint recognition functions into the LED panel display.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a top view of an LED panel display structure according to a first embodiment of the present invention;

FIG. 2 is an assembled sectional view of the LED panel display structure according to the first embodiment of the present invention;

FIG. 3 is an assembled side view of an LED panel display structure according to a second embodiment of the present invention; and

FIG. 4 is an assembled top view of an LED panel display structure according to a third embodiment of the present invention.

### DETAILED DESCRIPTION OF THE PREFERRED EMBODIMENTS

The present invention will now be described with some preferred embodiments thereof and by referring to the accompanying drawings. For the purpose of easy to understand, elements that are the same in the preferred embodiments are denoted by the same reference numerals.

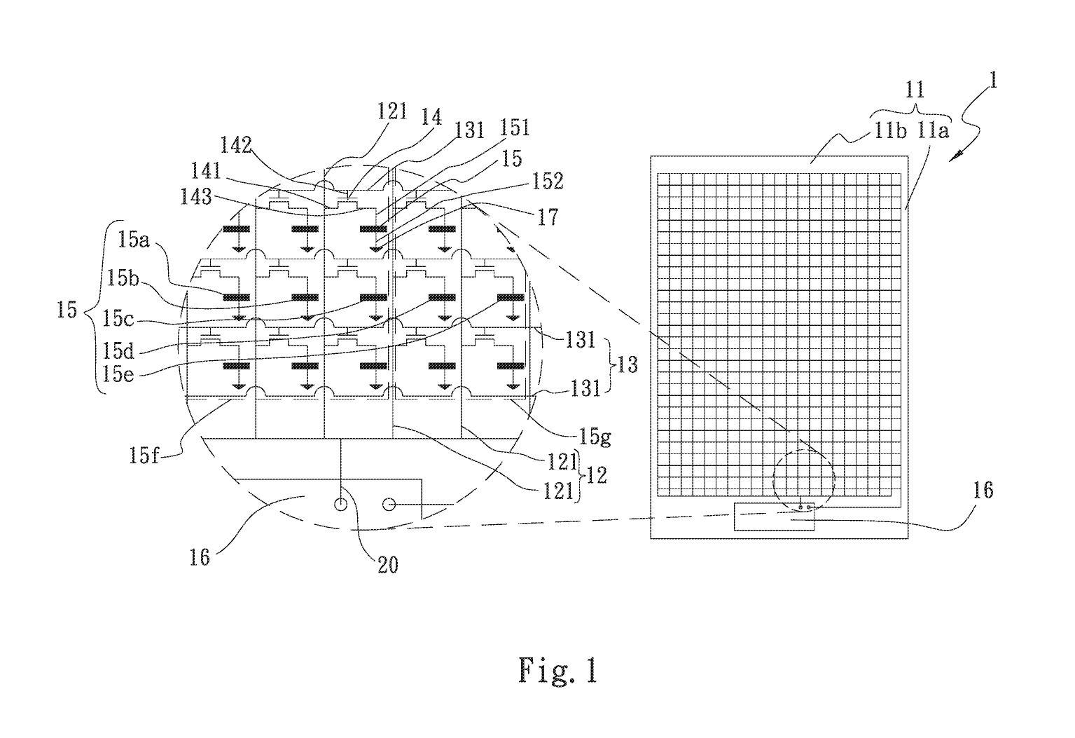

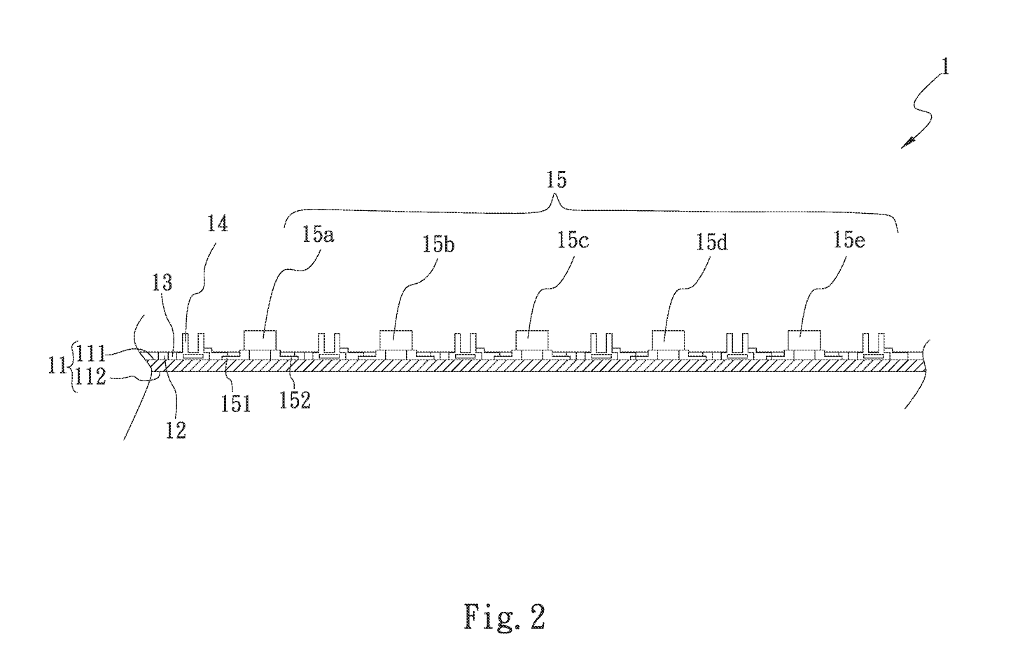

Please refer to FIGS. 1 and 2, which are top and assembled sectional views, respectively, of an LED panel display structure 1 according to a first embodiment of the present invention. As shown, the LED panel display structure 1 in the first embodiment includes a base member 11, a first electrode layer 12, a second electrode layer 13, a plurality of switch elements 14, a plurality of light-emitting diode (LED) elements 15, and a control chip 16.

The base member 11 has a first side 111 and an opposite second side 112. The base member 11 can be a glass substrate, a thin-film substrate or a flexible substrate.

The first electrode layer 12 includes a plurality of first electrode wirings 121, which are provided on the first side 111 of the base member 11 to extend longitudinally. The second electrode layer 13 includes a plurality of second electrode wirings 131, which are provided on the first side 111 of the base member 11 to extend transversely and cross over the first electrode wirings 121. The first and the second electrode layer 12, 13 are provided on the base member 11 by an etching process or a printing process. The first electrode wirings 121 are source signal line wirings, and the second electrode wirings 131 are gate signal line wirings.

The switch elements 14 are provided on the first side 111 of the base member 11. Each of the switch elements 14 includes a first pin 141, a second pin 142, and a third pin 143. The first pins 141 and the second pins 142 are electrically connected to the first electrode wirings 121 and the second electrode wirings 131, respectively. The switch elements 14 are thin-film transistors and are mainly used for signal switching.

The LED elements 15 are provided on the first side 111 of the base member 11. Each of the LED elements 15 includes a first lead 151 and a second lead 152. The first leads 151 are electrically connected to the above-mentioned third pins 143, and the second leads 152 are electrically connected to a ground 17. The LED elements 15 include red light-emitting diodes 15a, green light-emitting diodes 15b, blue light-emitting diodes 15c, infrared (IR) light-emitting diodes 15d and detectable infrared (IR) diodes 15e, which are spaced from one another when they are arranged on the base member 11. The LED elements 15 form a plurality of display blocks 15f. Each of the display blocks 15f can be a 5×5 array block or an even larger array block formed of the red, green and blue diodes 15a, b, c, the IR diodes 15d and the detectable IR diodes 15e, which are arrayed to space from one another. These array blocks are longitudinally and transversely extended on the base member 11. The IR diodes 15d and the detectable IR diodes 15e together form a plurality of sensing blocks 15g, which mainly perform the functions of touch point detection and fingerprint recognition.

The base member 11 includes a touch zone 11a and a non-touch zone 11b. The control chip 16 can be selectively provided in the touch zone 11a or the non-touch zone 11b.

During a system detection of fingerprint or palm print recognition, the IR LEDs 15d emit an IR band. When an object, i.e. a user's fingerprint or palm print, approaches the LED panel display structure 1, the IR band emitted from the IR LEDs 15d will be reflected by the object onto adjacent detectable IR LEDs 15e.

All the red LEDs 15a, green LEDs 15b, blue LEDs 15c, IR LEDs 15d and detectable IR LEDs 15e have an external length of 1 μm˜100 μm and an external width of 1 μm˜100 μm.

The control chip 16 is arranged on the first side 111 of the base member 11 and is electrically connected to the first and the second electrode layer 12, 13.

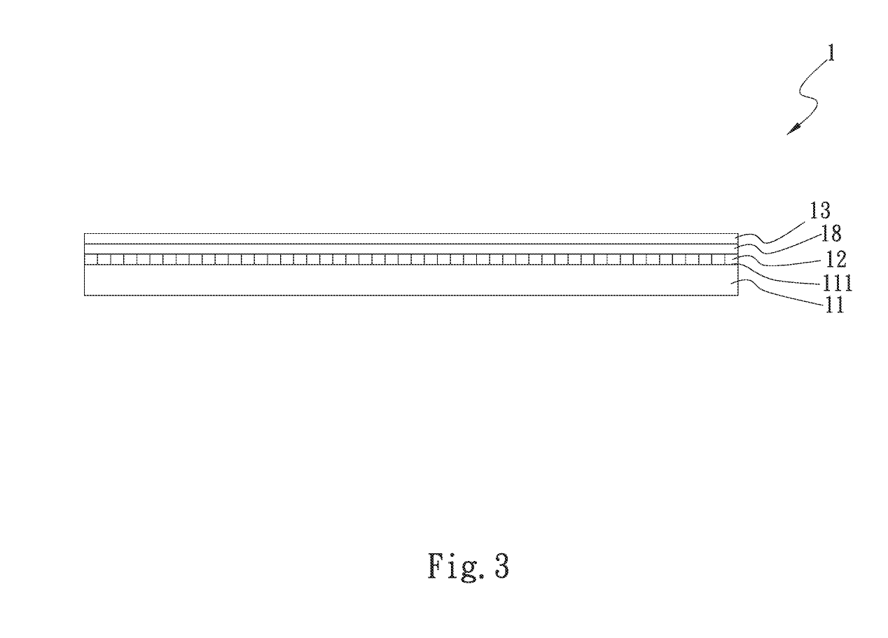

Please refer to FIG. 3, which is an assembled side view of the LED panel display structure 1 according to a second embodiment of the present invention. As shown, the second embodiment is generally structurally similar to the first embodiment, except for an insulating layer 18 that is further provided between the first and the second electrode layer 12, 13 to cover the first electrode layer 12 and the first side 111 of the base member 11. The second electrode layer 13 is provided on a top of the insulating layer 18.

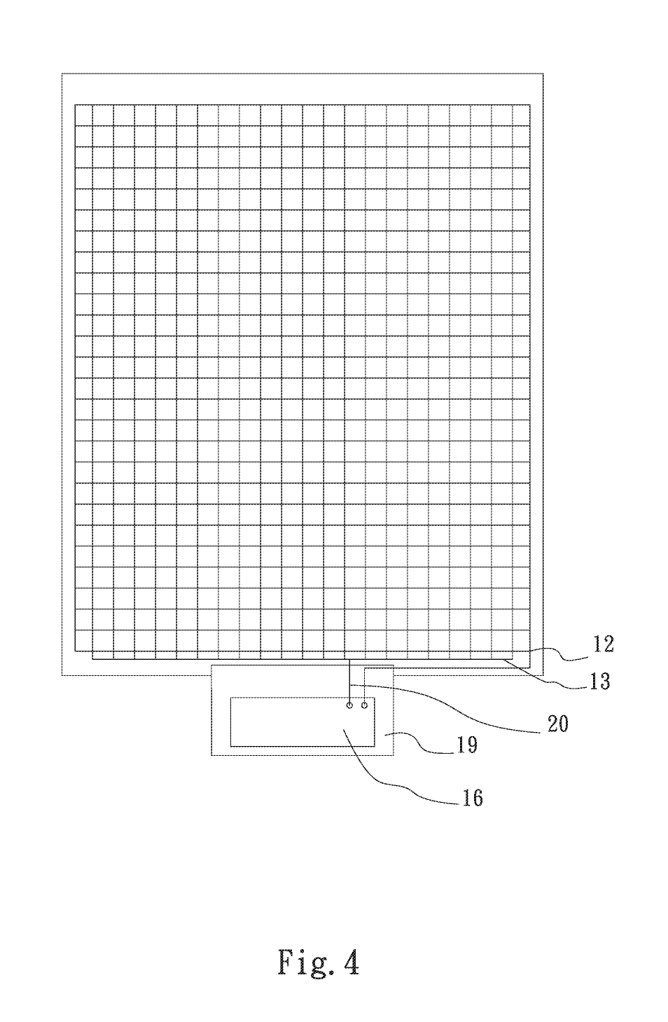

FIG. 4 is an assembled top view of the LED panel display structure according to a third embodiment of the present invention. As shown, the third embodiment is generally structurally similar to the first embodiment but further includes a flexible circuit board 19. In the third embodiment, the control chip 16 is attached to the flexible circuit board 19 using chip-on-board (COB) process and is electrically connected to the first and the second electrode layer 12, 13 via a plurality of circuit traces 20.

According to the present invention, the LED elements 15 and the switch elements 14 and the control chip 16 can be provided on the base member 11 using chip-on-board process or chip-on-glass process.

Unlike the conventional liquid crystal display (LCD), in which each row and each column of transistors are respectively controlled by one driver IC, the present invention integrates all driver ICs into one single control chip 16, which cooperates with a plurality of switch elements 14, i.e. the thin-film transistors, to control all the LED elements 15. Therefore, the present invention can save more space in each unit area for arranging more LED elements 15 to enable image quality of very high 2K or 4K resolution. That is, the LED panel display structure of the present invention not only enables reduced manufacturing cost and increased resolution, but also integrates the touch and fingerprint recognition functions into the display screen.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A light-emitting-diode (LED) panel display structure, comprising:
a base member having a first side and an opposite second side;
a first electrode layer including a plurality of first electrode wirings provided on the first side of the base member to extend longitudinally;
a second electrode layer including a plurality of second electrode wirings provided on the first side of the base member to extend transversely and cross over the first electrode wirings;
a plurality of switch elements being provided on the first side of the base member; each of the switch elements including a first pin, a second pin and a third pin; and the first and the second pins being electrically connected to the first and the second electrode wirings, respectively;
a plurality of LED elements being provided on the first side of the base member; each of the LED elements including a first lead and a second lead; the first leads being electrically connected to the third pins of the switch elements, and the second leads being electrically connected to a ground; and
a control chip being electrically connected to the first and the second electrode layer.

2. The LED panel display structure as claimed in claim 1, wherein the LED elements, the switch elements and the control chip are provided on the base member using a process selected from the group consisting of chip-on-board process and chip-on-glass process.

3. The LED panel display structure as claimed in claim 1, wherein the LED elements include red LEDs, green LEDs, blue LEDs, infrared (IR) LEDs and detectable IR LEDs.

4. The LED panel display structure as claimed in claim 1, wherein the first electrode wirings are source signal line wirings and the second electrode wirings are gate signal line wirings.

5. The LED panel display structure as claimed in claim 1, wherein the switch elements are thin-film transistors.

6. The LED panel display structure as claimed in claim 1, wherein the LED elements form a plurality of display blocks and a plurality of sensing blocks.

7. The LED panel display structure as claimed in claim 1, further comprising a flexible circuit board, and the control chip being attached to the flexible circuit board.

8. The LED panel display structure as claimed in claim 1, wherein the base member is selected from the group consisting of a glass substrate, a thin-film substrate and a flexible substrate.

9. The LED panel display structure as claimed in claim 1, wherein the base member includes a touch zone and a non-touch zone; and the control chip being selectively provided in one of the touch zone and the non-touch zone.

10. An LED panel display structure, comprising:
a base member having a first side and an opposite second side;
a first electrode layer including a plurality of first electrode wirings provided on the first side of the base member to extend longitudinally;
an insulating layer covering the first electrode layer and the first side of the base member;
a second electrode layer including a plurality of second electrode wirings provided on the insulating layer to extend transversely;
a plurality of switch elements being provided on the first side of the base member; each of the switch elements including a first pin, a second pin and a third pin; and the first and the second pins being electrically connected to the first and the second electrode wirings, respectively;
a plurality of LED elements being provided on the first side of the base member; each of the LED elements including a first lead and a second lead; the first leads being electrically connected to the third pins of the switch element, and the second leads being electrically connected to a ground; and
a control chip being electrically connected to the first and the second electrode layer.
